(19) United States
(12) Patent Application Publication
(10) Pub. No.: US 2026/0025116 A1
(43) Pub. Date: Jan. 22, 2026

(54) ADAPTIVE STEREO WIDTH CONTROL

(71) Applicant: DALI A/S, Nørager (DK)

(72) Inventors: Claus FUTTRUP, Hobro (DK); Thomas LOTZFELDT, Vadum (DK)

(21) Appl. No.: 18/775,124

(22) Filed: Jul. 17, 2024

(51) Int. Cl. H03G 3/30; H04S 3/00

(52) U.S. Cl. CPC H03G 3/3089; H04S 3/008

(57) ABSTRACT

A method of improving the listening experience when listening to music is provided. The object is to interfere as little as possible with the original music recording i.e. the input signal to the audio unit reproducing the music, but nevertheless provide a more full and wide stereo experience and thereby improved listening experience, particularly for replay installations where the loudspeakers are arranged in relatively close proximity to each other. The amount of stereo widening may sometimes be desired less than at other times. This is typically when the audio recording is already panned wide or produced including a certain amount of ambience and reverberation. At other times the level of widening can be increased giving a more exciting and “out-of-the-box” listening experience without side effects. An audio device is also provided.

### FIELD OF TECHNOLOGY

The following relates to a method for dynamically widening a stereo signal, adaptive to the input signal.

### BACKGROUND

It is often desirable to artificially engineer the output sound stage such that even for audio devices where the loudspeakers are arranged in close proximity to each other the emitted sound is experienced by the user as being wide, broad and full.

In the conventional art this has been attempted by numerous disclosures and devices.

WO20091027250A1 discloses a stereo widening system based on decorrelation. The phase response to the right and left channels are read and introduced into a filter. The filter is programmed such that at lower frequencies the phase between the right and left channels is retained, whereas at higher frequencies in the interval 300 to 3000 Hz the right and left channels are brought into counter phase. In the disclosure stereo widening is further achieved using decorrelation, which effectually is introducing delays such that the output signals are “mixed” by adding parts of the opposite signal with a slight delay to the actual output signal.

The manipulation of the signal in WO20091027250A1 in order to force the stereo widening effect is achieved by implementing the filters in the signal path, thereby interfering with the complete original signal.

This may cause detrimental side effects. Originally when the sound is first recorded the sound engineer will have tweaked and manipulated the recorded music in order to achieve a desired output. By introducing the already engineered signal to further manipulation as suggested in WO 20091027250A1 and other disclosures the sound is not reproduced as originally intended and the attempt during the replay of the music to further manipulate the signal in order to for example achieve a stereo widening effect, may cause the original music signal to be outputted with side-effects (overly space feeling, dampening of some frequencies etc.).

### SUMMARY

An aspect relates to applying adaptive stereo widening to a speaker system while considering the characteristics of the input signal. Stereo widening is especially beneficial to speaker systems with limited distance between the left and right speaker positions as is often the case for integrated products.

A requirement is that the amount of stereo widening must depend on the character of the input signal. Whenever the audio material is dry and narrow then widening can be increased with a minimum of side effects to achieve a more exciting and out-of-the box listening experience. Likewise, in case the audio production is already panned wide or already ambient and reverberant then widening is reduced not to exaggerate the effect.

Some methods for obtaining stereo enhancement are based on signal delays and added reverb. Embodiments of the applied method are different (no delays or reverb), and it does not interact more than necessary with the original signal.

Instead of a fixed amount of stereo widening embodiments of the implementation are making use of analysis of the incoming signal to determine how much widening can be added for the optimal listening experience across many different music productions. This DSP processing of the characteristics of the input signal is not done within the audio signal path. It's done “out-of-band” keeping the advanced processing and the delicate original audio signal separated.

The amount of widening to be added during any time of playback is determined by calculating a widening gain coefficient named G. This is done using a two-step approach which in combination estimates the level of stereo widening to add:
The amount of ambience, or anti-phase signal, is achieved using cross-correlation computations of the left and right input audio channels.
The level of monoaural type signal is achieved using Principal Component Analysis (PCA) to compute the direction of the stereo image (the principal axis) which is mapped to a center channel vector of length corresponding to the level of the center channel.

The proportion of the level of the center channel to the level of ambience (surround) signal is used to control the optimal amount of stereo widening. This is a core of embodiments of this DALI invention, applying decomposition of the input signal into surround channels and using the result to determine the optimal amount of widening for the stereo signal. Signal processing is done on a DSP using un-licensed and basic DSP arithmetic operations.

When the audio material is “dry”, and the listening experience is mostly “in-the-box” then widening is increased. And if the level of ambience or channel separation is high compared to the level of center channel audio then widening is reduced to minimize potential negative side effects as for example reverb of distant vocals. This is all happening seamlessly to the listener without noticeable adjustments of the amount of widening.

An aspect of embodiments of the present invention is therefore to interfere as little as possible with the original music recording i.e. the input signal to the audio unit reproducing the music, but nevertheless provide a more full and wide stereo experience and thereby improved listening experience, particularly for installations where the loudspeakers are arranged in relatively close proximity to each other.

The amount of stereo widening may sometimes be desired less than at other times. This is typically when the audio recording is already panned wide or produced including a certain amount of ambience and reverberation. At other times the level of widening can be increased giving a more exciting and “out-of-the-box” listening experience without side effects.

The word ‘panned’ is used in the traditional meaning as the act of placing or moving a sound anywhere in the stereo field of a stereo playback system. With panning, the sound sources can be placed in a way that they are perceived as coming from the left speaker, the right speaker, or from anywhere in between.

Embodiments of the present invention achieve this by a method of dynamically widening the stereo output of an audio device where a plurality of steps is executed where in

Step a: a PCA analysis is made on the input signals from left and right channels L_{orig} and R_{orig}, whereby the dominant stereo image vector y(k) and the rest vector q(k) orthogonal to y(k) are determined.
Step b: The center channel audio is uc(k)=Cc(k)*y(k)
where C_{c}(k)=2W_{L}W_{R}
Where W_{L} and W_{R} are weighting functions at a given sample step
Step c: a cross correlation analysis identifies a surround channel audio as uₛ(k)=Cₛ(k)*q(k) where (Cₛ) is

$${C}_{s} = 1 - {ρ}_{0} ( k )$$

where ρ₀ is the correlation coefficient, which may be approximated through a recursive algorithm

Step d: an ambience factor(S) is calculated as

$$S = {u}_{c} ( k ) / {u}_{s} ( k )$$

Where u_{c}(k) is the center channel audio and uₛ(k) is the surround channel audio
Step e: Widening gain G=(A*S−B)^{a} is applied to the original left and right input channels, where A is a scaling factor and B is an offset factor, both determined during testing, and where n is selected larger than 0, and for linear proportionality n=1.

A higher order function G(S) may also be applied. This of course occurs when n is larger than 1. A higher order function may in this connection also be contemplated as an exponential function, logarithmic function, or any other mathematical function which will impact the widening gain.

The factor A may be selected by testing for example in a lab, such that the scaling factor will ensure that the resulting widening gain performs as desired, i.e. influences the resulting output sound in a manner where the stereo experience is enhanced. Likewise the offset factor B may be determined such that the resulting influence of the widening gain G lies inside desired and determined limits in order to fulfill the requirement of providing an enhanced listening experience.

In summary the center and surround audio data are used to compute the level of stereo widening based on signal processing. This time varying and input signal dependent stereo widening is applied to the audio signal by adding nothing more to the signal than already present in the original input signal.

Embodiments of the new method are based on the same signal processing of the audio signal itself as implemented in some audio devices where a fixed widening factor is used in order to broaden the output signal. An example of such a device is marketed under the name DALI KATCH ONE which is the same applicants own earlier successfully marketed device. In this device the widening factor G is selected to be fixed at for example 0,7. Instead of a fixed amount of widening as is the case with the KATCH ONE embodiments of the invention is doing adaptive widening depending on the character of the input signal. This makes the “out-of-band” processing of the new method much more advanced.

In embodiments, the method is based on a two-step approach which in combination estimates the level of stereo widening that can be applied without side-effects:
The amount of ambience, or anti-phase signal, is achieved using cross-correlation computations of the left and right channel inputs
The level of center channel is achieved using Principal Component Analysis (PCA) to compute the direction of the stereo image (the principal axis) which is mapped to a center channel vector of length corresponding to the level of the center channel. Alternatively, analyzing the left and right input regarding correlated sound (e.g. cross correlation). In an embodiment the left and right channels do not necessarily play equally loud and therefore a Principal Component Analysis (PCA) is better than simple cross correlation.

The factor “A” in the equation above is a scale factor. It may be selected according to the application. In embodiments A may be 0.1, 1 or another factor in a similar range.

The proportion of center channel level to ambience (surround) level is used to control the amount of stereo widening. When the level of ambience is high, and the level of center channel is low then widening is reduced. And vice versa, if the level of ambience is low and the level of center channel is high (“in-the-box”), then widening is increased.

Furthermore, the factor B is determined during experiments and measurements on a given actual loudspeaker configuration, in order to achieve a measured widening gain within limits assuring that the complete audio impression for the listener is full as possible without excessive peaks or lows. For a system used in the development of embodiments of the present inventive method it was found that B should be selected as 0.11 in order to provide the optimum sound reproduction. B is an offset factor that may be chosen positive or negative, depending on the application. Typically, the factor B is selected within the range −1 to +1.

This continuous adaptive approach to dynamic stereo widening must happen seamless without noticeable adjustments of the widening factor. The adjustment is carried out in incremental steps where the speed of change is controlled. This is done in order to avoid rapid changes which may be noticed by the listener.

Furthermore, as is evident above the equipment/product tuning dependent factors A and B as well as minimum and maximum levels of G, see below, will be different from product to product.

Consequently, in a further advantageous embodiment of the inventive method in step e) a further comparison of the calculated widening gain G is made to predetermined maximum and minimum levels of the widening gain G, where the predetermined maximum and/or minimum levels are applied when the calculated widening gain is larger or smaller than the predetermined maximum and minimum levels.

The input signals have, as already discussed above, been produced, may be in a recording studio, to accommodate listening preferences and characteristics on typical playback devices in various setups and situations. It is not the intention of embodiments of the invention to alter the coloring or characters of the original recording as well as widening of the sound stage must be balanced not to produce any audio side- or artefact effects.

Minimum and maximum boundaries (maximum and minimum levels of widening gain) are defined not to exaggerate the level of widening. And individual steepness of up- and down ramps are used to slew the adaptations as well as to control that widening is ramping down faster than up. This can, for example, be appropriate at change of audio track without pause in between. For these reasons the predetermined maximum and minimum levels of widening gain G is between 1,1 and 0, for example, between 0,9 and 0,2.

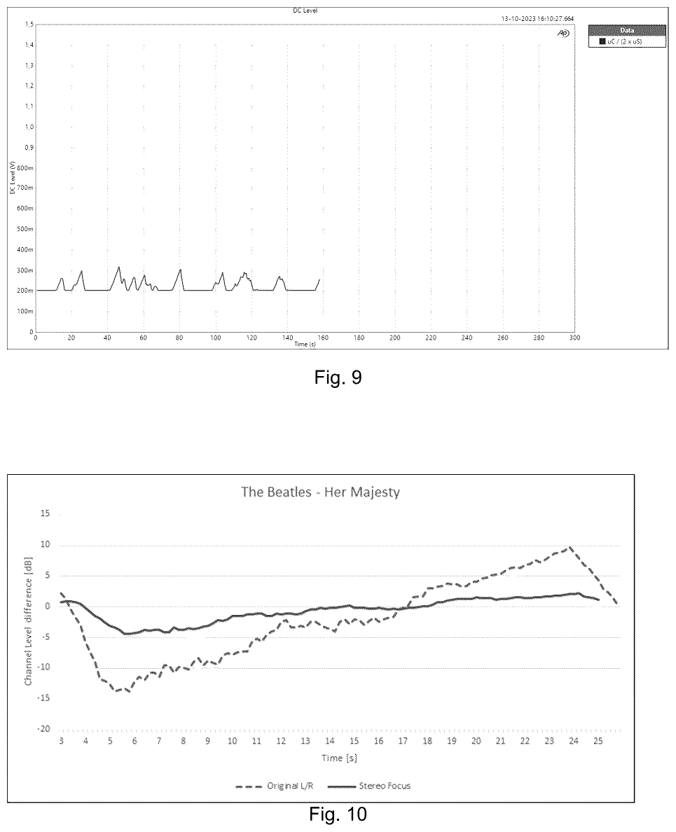

For special applications, where the stereo width is desired to be reduced, not widened, the gain factor can be computed negative by mirroring: G=−A×S+B or shifting: G=A×S−B−C, where C is a constant that ensures G is negative, for example C=−1. This is equivalent to adding a portion of left signal to right channel in phase, and vice versa. In this situation the circuitry operates as if a bypass of the signal inverter was installed, see dashed line 30 in FIG. 2, in a simplified circuitry. For example, for use with headphones, where standard techniques include adding crosstalk. This application may also benefit from adjusting the crosstalk for the signal in the adaptive way as described. The G factor may in the limit case be as low as −1 (minus one). When G=−1 the added left and right signals are gained by factor 1 and then added, in phase, to the left and right outputs. For example, in older recordings of for example Beatles tunes, drums and guitars are panned out to left and right channels shifting over time (FIG. 9). By introducing the Beatles music as input signals into embodiments of the present invention for G<0, the algorithm will “mix” the signals and output a signal where each channel/instrument is present in both output channels, essentially reducing the stereo effect. The degree to which channels are mixed depends on the input signal and the adaptive G factor.

During silence the inputs to the algorithm are zero and the computed center and surround estimates are also both zero. Hence, the calculation of G becomes undefined (co). This is the case in pause mode where it has shown that the G value is doing run-away. Time is then needed for the widening to converge after entering play state again i.e. an input different from 0.

To solve this a DetectPause solution has been implemented in the DSP. Whenever the level of the input signal drops below a defined level (for example −45 dB RMS) the widening starts adapting towards the lower limit of G (minimum levels of widening gain) getting ready for resuming play.

To make this happen the algorithm is fed a suitable input making the output converge while no signal is present. This has been implemented with an index selectable multiplexer switching between the audio signal and a tone input with 90° phase of the right channel relative to left channel. Note this tone is not added to the output signal, but only to the computing of G.

The mathematics to compute the level of center channel audio and the level of surround channel audio is based on an article presented at AES 2001 for computing 5-channel surround from a stereo input. The concept of embodiments of the present invention is to use this decomposition into multichannel audio as input to the processing of the adaptive stereo widening. That is, to compute the level of stereo widening based on the signal processing done to achieve the center and surround audio data. This time varying and input signal dependent stereo widening is applied to the audio signal by adding nothing more to the signal than already present in the original input signal. The signal processing for the multichannel decomposition is done using only discrete, and un-licensed, DSP arithmetic operations in the implementation.

The level of center channel audio is derived using Principal Component Analysis (PCA). PCA produces two vectors indicating the direction of the stereo image described by a dominant signal y(k) and a remaining signal q(k) (which is orthogonal).

PCA gives a useful 2-dimensional vector representation of a cloud of points (consecutive left and right channel audio samples) optimized for lowest average mean value and highest possible variance (longest length of the vector). In embodiments, the method is used in mathematics to extract information about certain observations from a multi-dimensional observation space by mapping into 2-dimensions without significant loss of probability.

The weighting functions W_{L} and W_{R} may be given by:

$${w}_{L} ( k ) = {w}_{L} ( k - 1 ) + μ y ( k - 1 ) \times [ {x}_{L} ( k - 1 ) - {w}_{L} ( k - 1 ) y ( k - 1 ) ]$$

$${w}_{R} ( k ) = {w}_{R} ( k - 1 ) + μ y ( k - 1 ) \times [ {x}_{R} ( k - 1 ) - {w}_{R} ( k - 1 ) y ( k - 1 ) ] .$$

With y(k−1) initially being zero the weighting functions will continue to be zero. “k” being the present sample where “k−1” is the previous sample. To avoid this start-up condition, a routine has been added that avoids zero output y(k) values.

The center channel audio u_{c}(k) and the surround channel audio uₛ(k) are computed by:

$$u c ( k ) = {c}_{C} ( k ) * y ( k ) and {u}_{S} ( k ) = {c}_{S} ( k ) * q ( k )$$

where y(k) and q(k) are the dominating and the remaining signals respectively:

The weighting functions w_{L}(k) and W_{R}(k) are given by the input signals x_{L}(k), x_{R}(k) and feedback output samples y(k−1):

Based on vector directions of the stereo image the projection on the center channel is:

$${c}_{C} = 2 {w}_{L} {w}_{R} .$$

The ambient surround channel level is computed by use of the remaining signal q(k). The remaining signal is scaled with respect to the input signal by use of the cross-correlation coefficient ρ₀(k) of the input signals.

Whenever the cross-correlation is low the scaling factor cs (k) becomes high and so does the level of the ambient surround channel.

$${c}_{s} = 1 - ρ0 ( k )$$

The DSP may not offer a processing block to compute the cross-correlation coefficient ρ₀(k). Therefore, it has been or may be approximated recursively by:

$${ρ}^{\text{?}} ( k ) = {ρ}^{\text{?}} ( k - 1 ) + γ \{ 2 {x}_{L} ( k ) {x}_{R} ( k ) - [ {{x}_{L} ( k )}^{2} + {{x}_{R} ( k )}^{2} ] {ρ}^{\text{?}} ( k - 1 ) \}$$

$$And :$$

$${ρ}_{0} = \{ \begin{matrix}ρ \text{?} & 0 \leq ρ \leq 1 \\ 0 \text{?} & otherwise\end{matrix}$$

$$\text{?} \text{indicates text missing or illegible when filed}$$

The γ is the step size.

Advantages of embodiments of the invention in short include the following:

Prior stereo widening, as implemented in KATCH ONE, allows for a fixed widening gain, which is chosen either by the designer, or possibly some adjustment that the end user can do (besides turning it off). KATCH ONE development indicated that too much stereo widening gain will make some music sound ‘distant’-‘hollow’- or reverberant like the music is played in a large hall (or church). Therefore, in the classic fixed gain implementation, the stereo widening must be limited yet it will still be possible to find some music where the effect is not as beneficial. Therefore, some listeners choose to turn off the fixed widening feature.

Embodiments of the present invention implements an automatic (stereo widening) and dynamic gain adjustment such that the consumer will find the stereo widening much more pleasant with a much larger range of music.

The conventional art R.A.C.E. algorithm works best if the user is placed right in front of two speakers (that are close to each other), yet it is often considered quite aggressive. Besides, the effectiveness of the RACE algorithm reduces when the listener is not placed correctly in the center line between the two speakers. This is the reason why embodiments of the present invention avoids recursive algorithms.

To sum up, advantages of embodiments of the invention include the following:

Embodiments of the invention require a low amount of DSP processing of the audio signal path itself, and e.g. no delay. The signal path itself is short.

Sufficiently low that it can be implemented in an existing product, as for example the KATCH ONE.

Although the Analysis and Adaptation part calculating G requires some calculations in a DSP it can run in a modest 6000 program instructions per sample DSP for example Analog Devices ADAU 1451, which is an advantage because a sound character of heavy processing is avoided.

There is no recursive part, i.e. no crosstalk cancelation.

The processing of the music signal itself is short and simple, maintaining the characteristic of the original sound.

The more advanced computation of the amount of widening is done out-of-band avoiding artefacts that can come with in-band DSP processing.

The characteristics and suggestive embodiments of the invention are specified in the appended claims.

### BRIEF DESCRIPTION

Some of the embodiments will be described in detail, with references to the following Figures, wherein like designations denote like members, wherein:

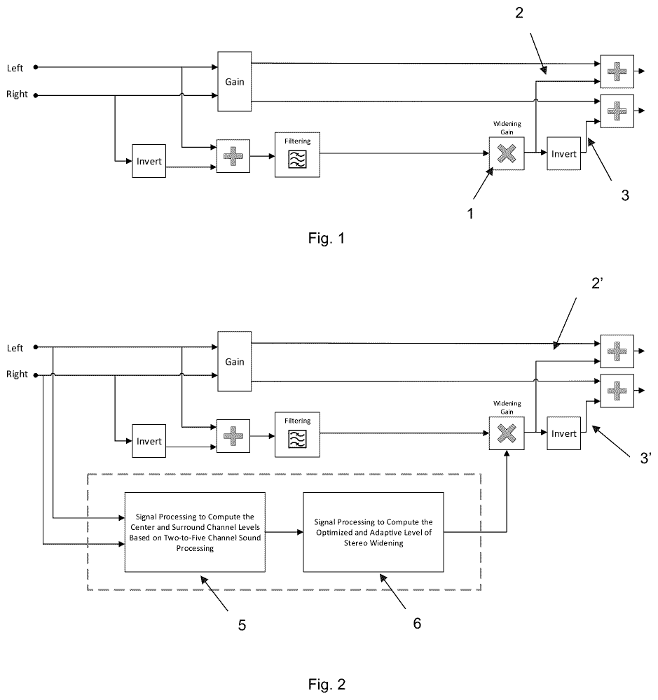

FIG. 1 illustrates a diagram of a traditional fixed gain system as in KATCH ONE;

FIG. 2 illustrates a schematic diagram of embodiments of the present invention;

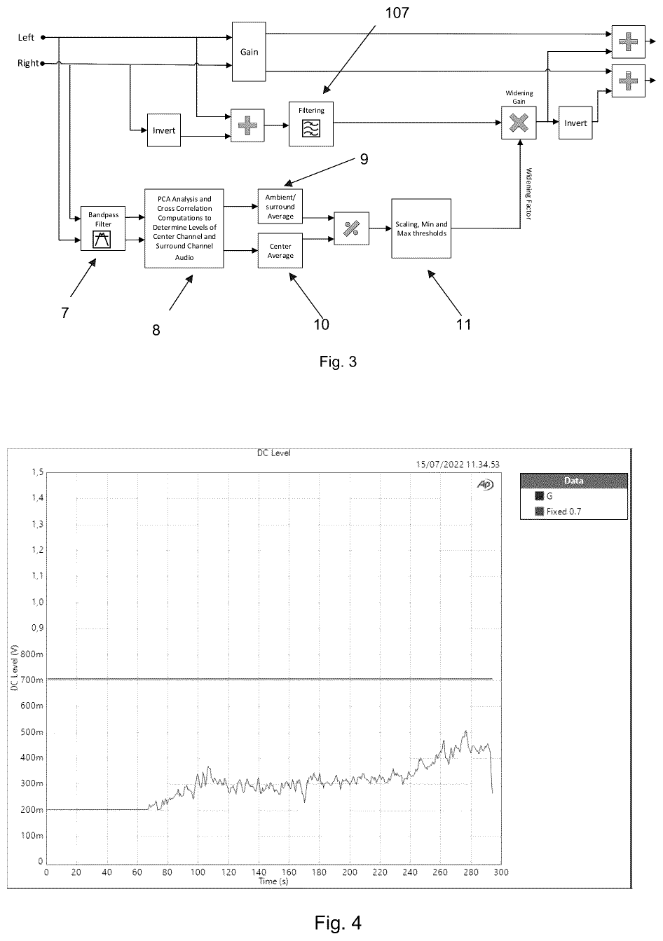

FIG. 3 illustrates a more detailed schematic diagram of embodiments of the invention;

FIG. 4 illustrates an example of widening and narrowing gain measurements according to embodiments;

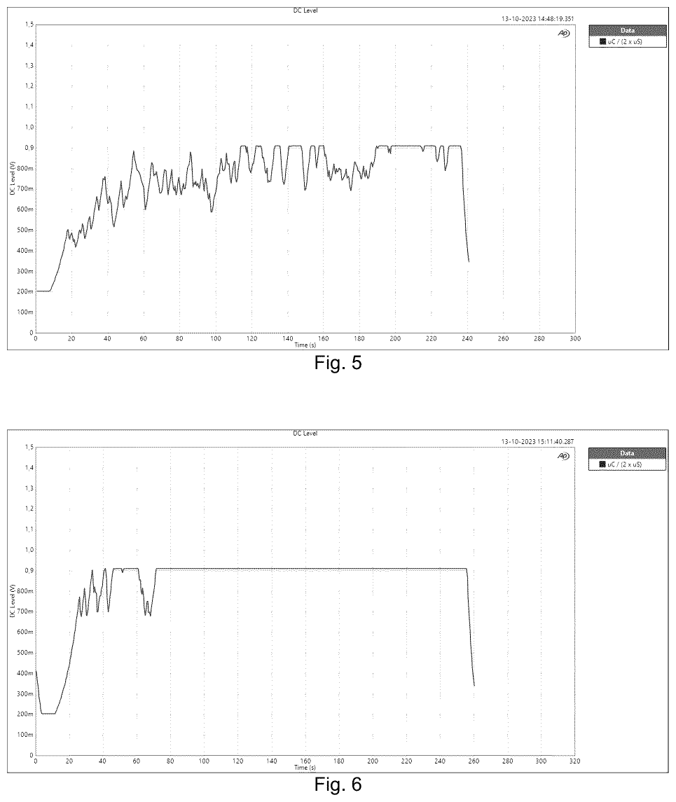

FIG. 5 illustrates a further example of widening and narrowing gain measurements according to embodiments;

FIG. 6 illustrates a further example of widening and narrowing gain measurements according to embodiments;

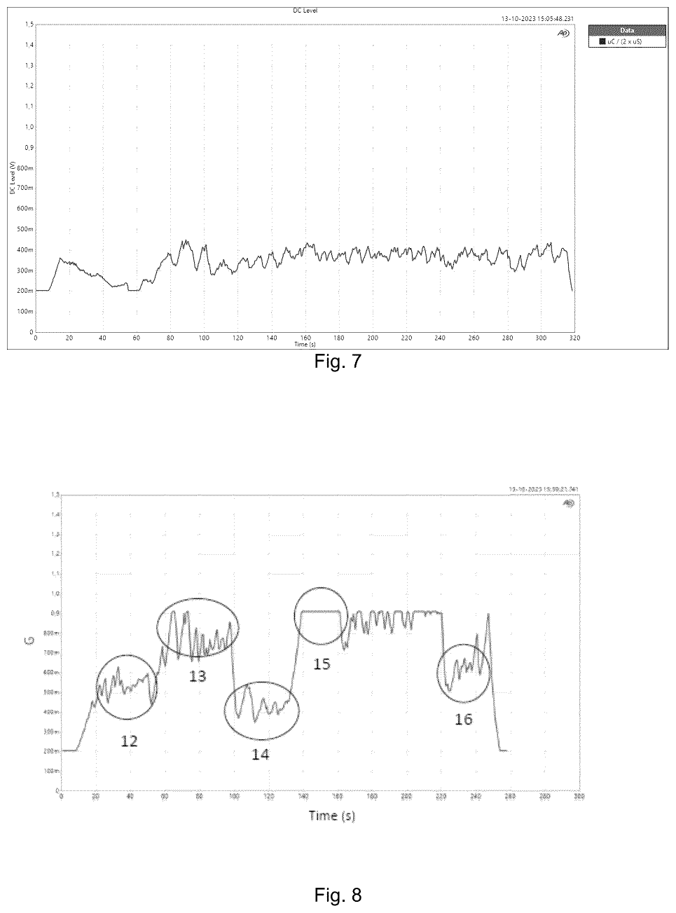

FIG. 7 illustrates a further example of widening and narrowing gain measurements according to embodiments;

FIG. 8 illustrates a further example of widening and narrowing gain measurements according to embodiments;

FIG. 9 illustrates a further example of widening and narrowing gain measurements according to embodiments;

FIG. 10 illustrates a further example of widening and narrowing gain measurements according to embodiments; and

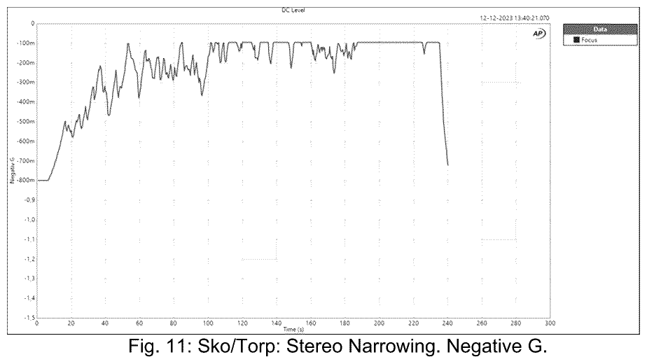

FIG. 11 illustrates a further example of widening and narrowing gain measurements according to embodiments.

### DETAILED DESCRIPTION

In FIG. 1 is schematically illustrated the diagram used for the KATCH ONE. The widening gain (G=0.7) is inserted directly in the signal path to the loudspeakers.

The left and right new signals (Lnew and Rnew) are derived as:

$$L new = ( L + 0.7 * ( L - R ) ) / ( 1 + 0.7 ) = L - 0.7 / 1.7 * R = L - 0.41 * R$$

$$R new = ( R - 0.7 * ( L - R ) ) / ( 1 + 0.7 ) = R - 0.7 / 1.7 * L = R - 0.41 * L$$

In KATCH ONE a constant widening factor of 0,7 is implemented. This was considered a good average widening factor for most music. It did achieve an average widening, but in some instances the constant widening factor introduced unwanted sound effects and/or excessive ambience in some cases.

With reference to FIG. 2 is schematically illustrated the diagram for embodiments of the present invention-contained inside the dashed rectangle (FIG. 2, item 4). The input signals (left and right) are introduced into a computing algorithm (4). First an analysis (5) of the incoming signals is performed. This analysis determines the level of ambience (diffuse sound) and the focus of the source signal. This analysis is then introduced into the algorithm in order to compute the adaptive/dynamic level of widening (6) optimized to the character of the input signal (as investigated in the analysis).

Thereafter the widening factor is introduced into the output signal (2′, 3′ in FIG. 2).

In FIG. 3 the schematic diagram is a little more detailed indicating the various routines the input signals are being subjected to. Initially the left and right input signals are introduced into a bandpass filter (7). The band pass filter (7) will select a frequency range of the input signal for computation of the widening gain G. The band pass filter frequency range could, for example, be 400 to 10.000 Hz. The filter 107 will filter frequencies above 200 Hz (low frequencies-bass) as it is desirable due to the propagation of low frequencies sounds to achieve an almost mono like signal. The selected signal range is thereafter introduced to a PCA analysis (8) in order to determine the nature of the input signals. In the process analyzing the center channel and the side channel(s) (surround channel).

The output center channel signal (10) and side channel signals (9) are thereafter transmitted/connected to a routine (11) where the predetermined maximum and minimum gain factors are compared (min and max thresholds) to the signal and applied if the signal falls outside the limits at this step (sample). For example, a gain factor is lower than the minimum predetermined gain factor will be substituted such that the gain will be for example 0.2 (or whatever is chosen/selected as the minimum gain factor). Finally, the signal is processed by applying the widening gain factor and transmitted to the loudspeaker(s).

In FIG. 4, embodiments of the method of the invention have been applied to Dire Straits song “on every street”. During the first approx. 60 seconds (x-axis) a minimum gain factor of 0.2 is applied to the input signal. Thereafter the algorithm, through the analysis of the signal applies varying widening factor, i.e. between 0.2 and 0,5. The music will not be added very much widening effect as the music from the producer side already has been engineered to provide a wide stereo experience i.e. the algorithm may reduce the widening gain, as there is already sufficient widening and gain for this particular part of the music.

The horizontal line at 0,7 (700m on the y-axis) corresponds to the widening factor KATCH ONE will apply to the same piece of music. Here KATCH ONE will alter the output much more than embodiments of the present invention causing what some listeners will characterize as too reverberant or distant perspective.

Turning to FIG. 5 the song “On a long lonely night” by Sko/Torp is indicated going through the method according to embodiments of the invention. In the beginning (0-5 sec) the minimum widening factor of 0.2 is applied until the algorithm has increased the above this initial level of 0.2. Throughout the next 230 seconds of music varying widening factor is applied in order to enhance the “fullness” of the played music. A few sequences (for example at 140 seconds) reach the maximum threshold of 0,9 and as such 0,9 is applied and not a may be higher factor calculated by the algorithm. This, as already discussed above, in order not to distort the played music outside limits where the distortion may be discernable and detrimental. This is the essence of the applying a dynamic widening factor to the signal. In comparison it is clear that embodiments of the present invention provide a much more varied and adapted widening factor as a result of the analysis of the input signal, than what is the case with KATCH ONE.

A further example is illustrated in FIG. 6 representing “smooth operator” by Basix. In this example the minimum and maximum thresholds of 0.2 and 0,9 (selected) are active for most of the song. Again, there is a clear difference with a constant widening gain factor of 700m as applied by KATCH ONE, and the widening gain factor applied by embodiments of the present invention. It may be deducted that embodiments of the present invention “forces” more stereo widening on the music than the KATCH ONE when it is feasible.

FIG. 7 Madonna “Vogue”. The left/right channel panning is high, keeping the widening G low, close to minimum limit of widening gain.

With reference to FIG. 8 is illustrated Madonna's song “Dark Ballet”. After the intro the vocal is in center (12) followed by the bass in center (13). The bass is limited by the widening factor G reaching 0,9 (indicated by short flat sections). The piano effects 14 is panned with some reverb, before the center bass (15) returns. Again, the bass is limited by the range of the widening factor at 0,9. And finally the vocals return (16). In this example the widening is selected in the range 0.2 to 0,9 causing the curve to have flat sections when it hits either of the upper or lower range limitations-resulting in the flat part of the curve.

Another example of a Beatles song is illustrated in FIG. 9. Here a remastered version (2009) of “when I'm sixty-four” is illustrated. The left/right panning is so high keeping the widening factor G low.

In FIG. 10 is illustrated an example of stereo narrowing as opposed to widening. This is a special case at which channel crosstalk is added in phase (described by negative G values). The music example used is (FIG. 10) the Beatles: Her Majesty. This music piece starts out with music panned to one side (5-6 seconds) whereafter the music is gradually panned to the opposite side output channel. The dashed curve is the untreated signal, whereas the full curve is the same piece of music having been led through adaptive widening according to embodiments of the present invention.

The figure shows what happens when mapping the widening gain to negative values. Both curves show the level difference, or channel separation, of the left and right outputs at the output of the signal processing while playing Beatles “Her Majesty”. The dotted curve shows the output channel difference without any signal processing applied. The output level of the original left channel signal is 14 dB higher than the right channel signal five seconds into the music. Including the signal processing, and a widening gain of −1, the channel separation is reduced to maximum 5 dB as shown by the solid curve.

A further example—Sko/Torp's song “On a long lonely night” of stereo narrowing (negative G) is illustrated in FIG. 11. The same song is illustrated with stereo widening in FIG. 5.

The music samples illustrated clearly indicate that different music is treated differently by the algorithm and the analysis, such that the specific character of the music is taken into account when reproducing it with embodiments of the present inventions method.

It is clear that with dynamic stereo widening as presented with embodiments of the present invention the step length—i.e. the time period between each point/sample which is introduced into the algorithm, is very important. On one hand the step length shall be short enough to adapt from maximum widening to minimum widening during the typical pause between music tracks. And adaptation speed must also be slow enough not to make rapid changes to the widening amount, based on a few audio samples, during music play. By cutting out certain frequencies by the thresholds and not having recursions and a low amount of DSP and a special routine taken care of situations where 0 appears (pause in the music) the method is able to react seamlessly and efficient to the input signal resulting in dynamic stereo widening without interference from the listener. This is achieved by the complete implementation including the bandpass filtering, DSP processing, signal pause detections and adaptation speed tuning, as above.

Although the present invention has been disclosed in the form of embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements. The mention of a “unit” or a “module” does not preclude the use of more than one unit or module.

1. A method of dynamically adaptive widening stereo output of an audio device comprising:
Step a: a PCA analysis is made on input signals from left and right channels L_{orig} and R_{orig}, wherein a dominant stereo image vector y(k) and a rest vector q(k) orthogonal to y(k) is determined;
Step b: a center channel audio is u_{c}(k)=C_{c}(k)*y(k)
where C_{c}(k)=2W_{L}W_{R}
Where W_{L} and W_{R} are weighting functions at a given sample step
Step c: a cross correlation analysis identifies a surround channel audio as
uₛ(k)=Cₛ(k)*q(k) where (Cₛ) is
$${C}_{s} = 1 - {ρ}_{0} ( k )$$
Step d: an ambient factor(S) is calculated as
$$S = {u}_{c} ( k ) / {u}_{s} ( k )$$
Where u_{c}(k) is the center channel audio and uₛ(k) is the surround channel audio
Step e: Widening gain G=(A*S−B)^{a} is applied to the original left and right input channels, where A is a scaling factor and B is an offset factor, both determined during testing, and where n is selected larger than 0.

2. The method according to claim 1, wherein in step e, a further comparison of the calculated widening gain G is made to predetermined maximum and minimum levels of the widening gain G, where the predetermined maximum and/or minimum levels are applied when the calculated widening gain G is larger or smaller than the predetermined maximum and minimum levels.

3. The method according to claim 2, wherein the predetermined maximum and minimum levels of widening gain G is between 2 and 0.

4. The method according to claim 2, wherein the widening gain G is negative, when crosstalk (crossfeed) is desired such that G=A+S−B−C, where C is a constant that ensures G is a negative value.

5. The method according to claim 2, wherein the widening gain G is negative, when crosstalk (crossfeed) is desired such that G=−A*S+B.

6. The method according to claim 1 wherein the weighting functions are further given by
$${w}_{L} ( k ) = {w}_{L} ( k - 1 ) + μ y ( k - 1 ) \times [ {x}_{L} ( k - 1 ) - {w}_{L} ( k - 1 ) y ( k - 1 ) ]$$
$${w}_{R} ( k ) = {w}_{R} ( k - 1 ) + μ y ( k - 1 ) \times [ {x}_{R} ( k - 1 ) - {w}_{R} ( k - 1 ) y ( k - 1 ) ] .$$

7. The method according to claim 6, wherein when y(k−1) is 0 a value different from 0 is inserted into the weighting functions.

8. The method according to claim 1, wherein the scaling factor A is selected between 0.1 and 1.

9. The method according to claim 1, wherein the offset factor B is selected between −1 and 1.

10. The method according to claim 1, wherein a DetectPause condition is implemented to avoid division by zero.

11. The method according to claim 1, wherein in step e the scaling factor A is in a range of 0.01 to 0,99 and wherein the offset factor B is in a range of 0.01 to 0,99.

12. The method according to claim 1, wherein n is selected larger than 1.

13. The method according to claim 1, wherein in step e, a different polynomial expression, or logarithmic or exponential or other mathematical expression, is used for i calculation of the widening gain G.

14. The method according to claim 1, wherein initially the left and right input signals are introduced into a bandpass filter and where the band pass filter will select a frequency range of the input signal for computation of the widening gain G, wherein the band pass filter frequency range is selected between 400-10000 Hz.

15. The method according to claim 2, wherein different music pieces are treated differently by the method and the analysis, such that a specific character of the different music pieces is taken into account and where a step size—i.e. a time period between each point/sample which is introduced into the method steps a) through e), are short enough to adapt from maximum widening to minimum widening during a typical pause between music tracks.

16. The method according to claim 15, wherein the step size is a fixed size or a variable step size.

17. The method according to claim 15, wherein adaptation speed is slow enough not to make rapid changes to the widening amount, based on a few audio samples, during music play which is achieved by cutting out certain frequencies by the predetermined maximum and/or minimum levels and not having recursions and a low amount of DSP and a special routine implemented where 0 appears (pause).

18. An audio device comprising an input facility, a computation unit, an amplifier, and a stereo output means, wherein the computation unit is configured to perform the method of dynamically adaptive widening stereo output of claim 1.
